(19) United States
(12) Patent Application Publication
(10) Pub. No.: US 2025/0113534 A1
(43) Pub. Date: Apr. 3, 2025

(54) METHOD FOR PRODUCING A TRANSISTOR DEVICE AND TRANSISTOR DEVICE

(71) Applicant: Infineon Technologies Austria AG, Villach (AT)

(72) Inventors: Markus Rochel, Radebeul (DE); Christian Fachmann, Villach (AT); Franz Hirler, Isen (DE); Winfried Kaindl, Unterhaching (DE)

(21) Appl. No.: 18/896,212

(22) Filed: Sep. 25, 2024

(30) Foreign Application Priority Data
Sep. 29, 2023 (DE) 102023126721.3

(51) Int. Cl. H10D 30/66; H10D 30/01; H10D 64/27

(52) U.S. Cl. CPC H10D 30/668; H10D 30/0297; H10D 64/519

(57) ABSTRACT

Disclosed is method for producing a transistor device and a transistor device. The transistor device includes a gate arrangement. The gate arrangement includes: a plurality of gate electrodes, each gate electrode being arranged in a respective gate trench extending from a first surface of a semiconductor body into the semiconductor body and dielectrically insulated from the semiconductor body by a respective gate dielectric; an insulating layer above the first surface of the semiconductor body and the gate electrodes; at least one contact opening in the insulating layer above each gate electrode; a plurality of contact fingers, each contact finger being connected to a respective gate electrode in a respective contact opening; and a connector connecting the contact fingers with each other.

### TECHNICAL FIELD

This disclosure relates in general to a method for producing a transistor device, in particular, for producing a gate arrangement of a transistor device.

### BACKGROUND

A gate arrangement of a transistor device may include a plurality of gate electrodes that are arranged in trenches of a semiconductor body and are dielectrically insulated from body regions of the transistor device by a gate dielectric. The gate arrangement may further include a gate runner and gate fingers formed above a surface of the semiconductor body and insulated from the semiconductor body. The gate fingers are connected between the gate runner and the gate electrodes.

A thickness of the gate dielectrics affects the threshold voltage of the transistor device. The threshold voltage is the voltage level of a gate-source voltage at which the transistor device changes from an off-state (blocking state) to an on-state (conducting state). The gate-source voltage is a voltage applied between the gate electrodes and a source node during operation of the transistor device.

There is a need for a robust gate arrangement that provides for a defined threshold voltage.

### SUMMARY

One example relates to a method. The method includes forming gate electrodes such that each gate electrode is arranged in a respective one of gate trenches extending from a first surface of a semiconductor body into the semiconductor body and is dielectrically insulated from the semiconductor body by a respective one of gate dielectrics, forming an insulating layer above the first surface of the semiconductor body and the gate electrodes, forming at least one contact opening in the insulating layer above each gate electrode, forming contact fingers, wherein each contact finger is connected to a respective gate electrode in a respective contact opening, and forming a connector connecting the contact fingers with each other.

Another example relates to a transistor device. The transistor device includes a gate arrangement. The gate arrangement includes gate electrodes each arranged in a respective one of gate trenches extending from a first surface of a semiconductor body into the semiconductor body and dielectrically insulated from the semiconductor body by a respective one of gate dielectrics, an insulating layer above the first surface of the semiconductor body and the gate electrodes, at least one contact opening in the insulating layer above each gate electrode, contact fingers, wherein each contact finger is connected to a respective gate electrode in a respective contact opening, and a connector connecting the contact fingers with each other.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIGS. 1A-1D and 2A-2D illustrate one example of a method for forming a gate arrangement of a transistor device, wherein the gate arrangement includes gate electrodes in trenches of a semiconductor body, contact fingers, and a connector;

FIG. 3 schematically illustrates a top view of one portion of the gate arrangement;

FIG. 4 illustrates one example of a contact opening in an insulating layer according to one example;

FIGS. 5A-5C and 6A-6C illustrate one example of a method for forming gate dielectrics and gate electrodes of the gate arrangement in gate trenches of a semiconductor body;

FIGS. 7A-7B and 8A-8B illustrate one example of a method for forming the contact fingers and the connector;

FIG. 9 illustrates a portion of a gate arrangement according to another example;

FIGS. 10A-10B illustrate top views of transistor devices according to different examples;

FIG. 11 schematically illustrates transistor cells of the transistor device according to one example; and

FIG. 12 schematically illustrates a detail of transistor cells of the type illustrated in FIG. 11.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

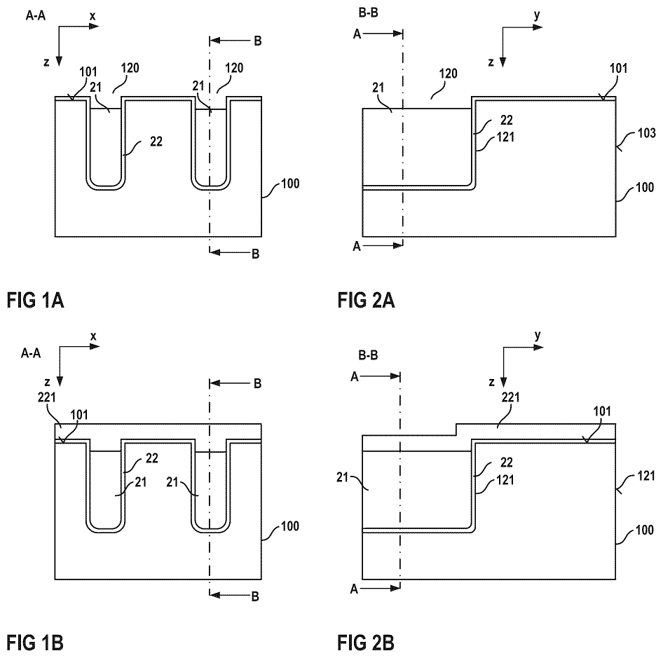

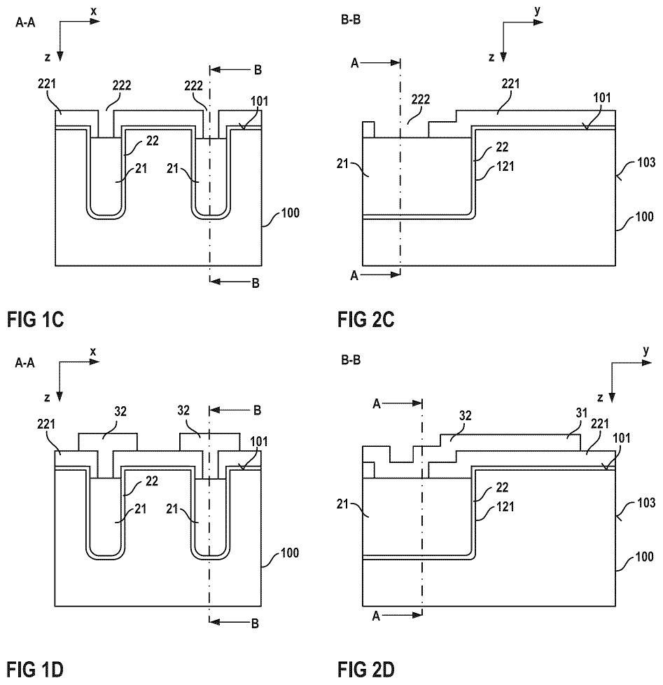

FIGS. 1A-1D and 2A-2D illustrate one example of a method for forming a gate arrangement of a transistor device. The gate arrangement includes a plurality of gate trenches 120 that each extend from a first surface 101 of a semiconductor body 100 into the semiconductor body 100. According to one example, the gate trenches 120 are essentially parallel to each other.

FIGS. 1A-1D illustrate a vertical cross-sectional view of one portion of the semiconductor body 100 in a first section plane A-A, which is essentially perpendicular to a longitudinal direction of the gate trenches 120. FIGS. 2A-2D illustrate a vertical cross-sectional view of one portion of the semiconductor body 100 in a second section plane B-B, which cuts through a portion of one of the gate trenches 120 and is essentially perpendicular to the first section plane A-A.

The gate trenches 120 are spaced apart from each other in a first lateral direction x of the semiconductor body 100. The longitudinal direction of the gate trenches 120 corresponds to a second lateral direction y of the semiconductor body 100. Each of the gate trenches 120 includes a first longitudinal end and a second longitudinal end spaced apart from the first longitudinal end in the longitudinal direction. FIGS. 2A-2D each illustrate the first longitudinal end 121 and an adjoining trench portion of one gate trench 120. The second longitudinal end is not illustrated in FIGS. 2A-2D.

Referring to FIGS. 2A-2D, the first longitudinal end 121 is spaced apart from a sidewall 103 of the semiconductor body 100. It should be noted that the processes explained in the following are processes that may take place on a wafer level. That is, the processes are applied to a wafer that includes a plurality of semiconductor bodies (semiconductor dies) which are separated from one another at the end of the manufacturing process. Thus, at the time of performing the processes illustrated in FIGS. 1A-1D and 2A-2D the sidewall 103 may not have been formed, yet. Thus, reference number 103 either denotes the sidewall of the semiconductor body 100 or denotes the position of the sidewall of the semiconductor body 100 in the wafer.

The semiconductor body 100 includes a monocrystalline semiconductor material. The semiconductor material is silicon (Si) or silicon carbide (SiC), for example.

Referring to FIGS. 1A and 2A, the method includes forming a plurality of gate electrodes 21 such that each gate electrode 21 is arranged in a respective one of the gate trenches 120 and is dielectrically insulated from semiconductor material of the semiconductor body 100 by a gate dielectric 22. As illustrated, the gates dielectrics 22 may be formed by a gate dielectric layer that covers bottoms and sidewalls of the gate trenches 120 and also covers the first surface 101 of the semiconductor body 100.

According to one example, the gate dielectrics 22 include an oxide such as silicon oxide (SiO₂). The gate electrodes 21 are electrically conducting and include an electrically conducting material. Examples of the electrically conducting material include a doped polycrystalline semiconductor material such as polysilicon, a metal such as aluminum, copper, titanium, or tungsten, or a silicide.

Referring to FIGS. 1B and 2B, the method further includes forming an insulating layer 221 above the first surface 101 of the semiconductor body 100 and above the gate electrodes 21 formed in the gate trenches 120. The insulating layer 220 is an electrically insulating layer and includes an oxide, a nitride, or combinations thereof, for example. According to one example, the insulating layer 221 is a homogeneous layer including only one electrically insulating material. According to another example, the insulating layer 221 includes two or more electrically insulating sub-layers that are formed one above the other. The insulating layer 221 is formed using a deposition process, for example.

According to one example, the insulating layer 221 is thicker than the dielectric layer forming the gate dielectrics 22. According to one example, a thickness of the insulating layer 221 is between 2 times and 5 time a thickness of the dielectric layer forming the gate dielectrics 22. According to one example, the thickness of the gate dielectrics is between 60 nanometers (nm) and 150 nm, and the thickness of the insulating layer 220 is between 150 nanometers and 500 nanometers, for example.

In the example illustrated in FIGS. 1B and 2B, the dielectric layer forming the gate dielectric 22 remains on top of the first surface 101 before forming the insulating layer 221. This, however, is only an example. According to another example, the insulating layer 221 is removed from the first surface 101 before forming the insulating layer 221, or the thickness of the dielectric layer on top of the first surface 101 is reduced before forming the insulating layer 221.

Referring to FIGS. 1C and 2C, the method further includes forming contact openings 222 in the insulating layer 221 above the gate electrodes 21, so that at least one contact opening 222 is formed in the insulating layer 221 above each of the gate electrodes 21. Forming the contact openings 222 may include an etching process, such as an anisotropic etching process, using an etch mask (not illustrated).

According to one example illustrated in FIGS. 2C, the contact opening 222 is spaced apart from the longitudinal end 121 of the gate trench 120. According to one example, the contact opening is close to the longitudinal end 121. This may include that a distance between the contact opening 222 and the longitudinal end 121 is between 0.5 micrometers and 10 micrometers, for example.

According to one example, two contact openings are formed in the insulating layer 220 above each of the gate electrodes 21, a first contact opening close to the first longitudinal end 121 and a second contact opening close to the second longitudinal and (not illustrated in FIGS. 2A-2D). According to another example, only one contact opening is formed in the insulating layer 220 above each of the gate electrodes 21 close to the first longitudinal end 121. According to another example, two contact openings are formed in the insulating layer 221 above gate electrodes 21 of a first group of gate electrodes and only one contact opening is formed in the insulating layer 221 above gate electrodes 21 of a second group of gate electrodes different from the first group.

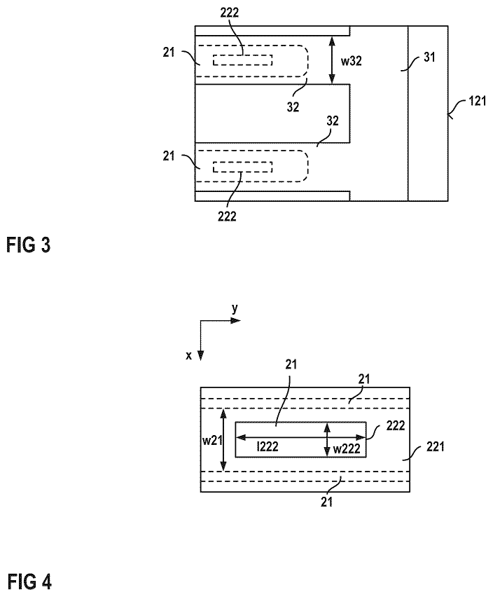

Referring to FIGS. 1D and 2D and referring to FIG. 3, which shows a top view of the gate arrangement illustrated in FIGS. 1D and 2D, the method further includes forming a connector 31 and contact (gate) fingers 32 above the insulating layer 221. Each of the contact fingers 32 is connected to a respective gate electrode 21 via a respective contact opening 222 in the insulating layer 221. The connector 31 connects the contact fingers 32 with each other. Each of the contact fingers 32 and the connector 31 includes an electrically conducting material such as doped polysilicon, or a metal. According to one example, the contact fingers 32 and the connector 31 are formed by the same process. One example of such process is explained herein further below.

The connector 31 connecting the gate fingers 32 with each other may act as a field electrode (field plate) in the finished transistor device and may therefore also be referred to as field electrode. Furthermore, the connector 31 may also be referred to as gate runner, wherein a further gate runner may be formed in addition to the connector 31 as explained herein further below.

FIG. 4 illustrates one contact opening 222 in the insulating layer 221 above one gate electrode 21 in greater detail. According to one example, the contact opening is essentially rectangular and has a width w222 in the first lateral direction x of the semiconductor body 100 and a length l222 in the second lateral direction y of the semiconductor body 100. According to one example, the length l222 is larger than a width w222. Furthermore, according to one example, the width w222 of the contact opening 222 is smaller than a width w21 of the gate electrode 21. According to one example, the width w21 of the gate electrode 21 is selected from between 0.5 micrometers and 2 micrometers, for example.

According to one example, the width w222 of the contact opening 222 is selected from between 0.3 micrometers (300 nanometers, nm) and 0.8 micrometers (800 nm), and the length l222 of the contact opening 222 is selected from between 0.5 micrometers (500 nm) and 10 micrometers, for example. As explained herein further below, the connector 31, via the contact fingers 32, connects the gate electrodes 21 to a gate pad of the transistor device.

An electrical resistance between one gate electrode 21 and the connector 31 is dependent on different parameter such as, for example, the size of the respective contact opening 222 (which is given by the length l222 multiplied with the width w222); the conductivity of the material of the respective contact finger 32; and the length and the cross-sectional area of the respective gate finger 32. The “cross-sectional area” of one gate fingered 32 is given by a width w32 (see FIG. 3) multiplied with a thickness of the electrically conducting material forming the gate finger 32.

As explained in detail herein further below, each of the gate electrodes 21 is part of one or more transistor cells of the transistor device. Each of these transistor cells can be operated in an on-state (conducting state) or an off-state (blocking state). Basically, the transistor device switches on or off dependent on a drive signal applied to the gate pad explained herein further below, wherein the transistor device switches on when the drive signal has an on-level or switches off when the drive signal has an off-level. There may be a delay time between a time instance at which the drive signal changes from the off-level to the on-level (or vice versa) and the individual transistor cells switch on (or switch off). This delay time, inter alia, is dependent on the electrical resistance of the gate fingers. In the gate arrangement according to FIGS. 1D, 2D, 3 the electrical resistance of one contact finger can be adjusted in various ways to either achieve that the individual transistor cells switch on after the same delay time or switch on after different delay times.

The electrical resistance between one gate electrode 21 and the connector 31 is dependent on different parameters such as, for example, the size of the respective contact opening 222 (which is given by the length l222 multiplied with the width w222); the conductivity of the material of the respective contact finger 32; and the length and the cross-sectional area of the respective gate finger 32. The “cross-sectional area” of one gate fingered 32 is given by a width w32 (see FIG. 3) multiplied with a thickness of the electrically conducting material forming the gate finger 32.

According to one example, the gate fingers include doped polysilicon. In this example, the conductivity of each gate finger 32 is dependent on the doping concentration of the polysilicon forming the respective gate finger 32. According to one example, a doped polysilicon layer is deposited and the contact fingers and the connector 31 is formed based on the deposited polysilicon layer. In this example, the polysilicon layer, at each position, essentially has the same conductivity. According to another example, an intrinsic (non-doped) polysilicon layer is deposited and the polysilicon layer is doped by implanting dopant atoms into the polysilicon layer. In this example, different contact fingers 32 can be differently doped, so that contact fingers 32 with different conductivities are obtained.

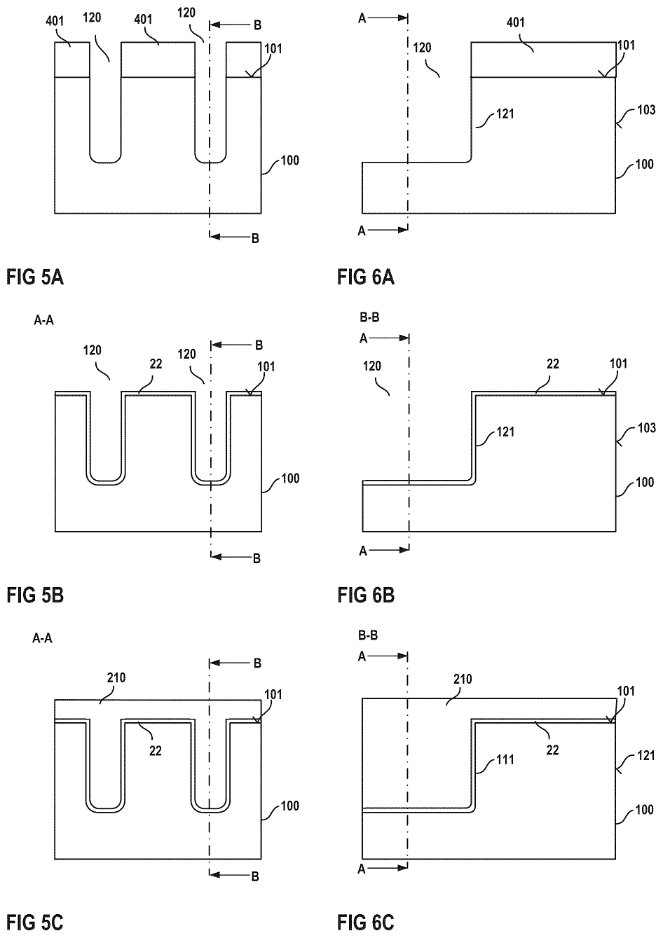

FIGS. 5A-5C and 6A-6C illustrate one example of a method for forming the gate electrodes 21 and the gate dielectrics 22 in the gate trenches 120 of the semiconductor body 100. FIGS. 5A-5C show a vertical cross-sectional view of one portion of the semiconductor body 100 in the first section plane, and FIGS. 6A-6C illustrate a vertical cross-sectional view of one portion of the semiconductor body 100 in the second section plane B-B.

Referring to FIGS. 5A and 6A the method includes forming the gate trenches 120 in the first surface 101 of the semiconductor body 100. Forming the gate trenches 120 may include an etching process such as an anisotropic etching process. The etching process includes forming an etch mask 401 on top of the first surface 101 and etching the gate trenches 120 into those sections of the first surface 101 not covered by the etch mask 401. According to one example, the gate trenches 120 are etched to have a depth of between 0.5 micrometers and 5 micrometers, in particular between 1 micrometer and 3 micrometers.

Referring to FIGS. 5B and 6B, the method further includes forming the gate dielectric layer that forms the gates dielectrics 22 in the gate trenches 120. According to one example, forming the gate dielectric layer includes a thermal oxidation process after removing the etch mask 401. In this example, the gate dielectric layer includes a semiconductor oxide, such as silicon oxide.

Referring to FIGS. 5C and 6C, the method further includes forming a gate electrode layer 210 that fills the gate trenches 120 and that may cover those portions of the gate dielectric layer formed above the first surface 101. Forming the gate electrode layer 210 includes depositing the gate electrode layer 210, for example. In order to achieve gate electrodes 21 of the type illustrated in FIGS. 1A and 2A, the method further includes removing the gate electrode layer 210 at least from above the first surface 101 of the semiconductor body 100. According to one example, this includes an etching process that etches the material of the gate electrode layer 210 selectively relative to the gate dielectric layer 22. According to one example, the etching process is performed such that the gate electrode layer 210 is not only removed from above the first surface 101, but also portions of the gate electrode layer 210 are removed from upper sections of the gate trenches 120, so that the gate electrodes 21, in the vertical direction z of the semiconductor body 100, are spaced apart from the first surface 101. The “vertical direction z” is essentially perpendicular to the first surface 101 of the semiconductor body 100.

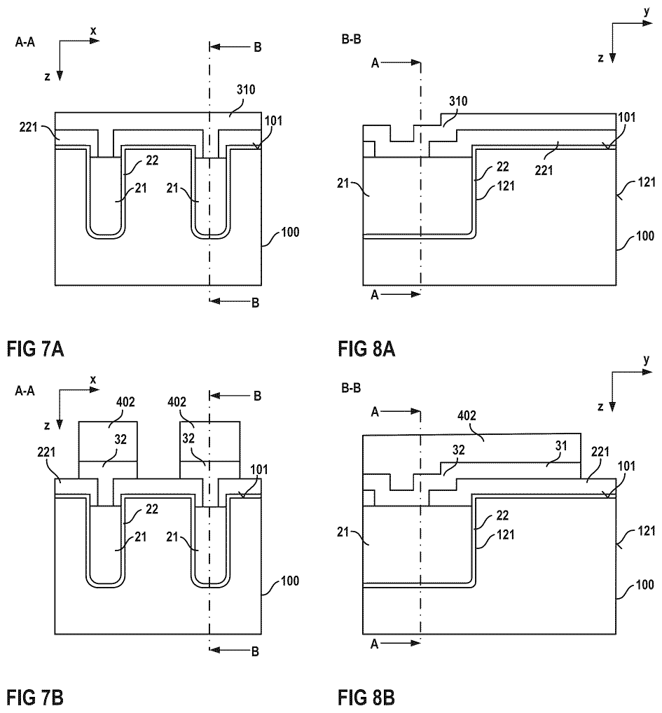

FIGS. 7A-7B and 8A-8B illustrate one example of a method for forming the contact fingers 32 and the connector 31. FIGS. 7A-7B show a vertical cross-sectional view of one portion of the semiconductor body 100 in the first section plane, and FIGS. 8A-8B illustrate a vertical cross-sectional view of one portion of the semiconductor body 100 in the second section plane B-B.

Referring to FIGS. 7A and 8A, the method includes forming an electrically conducting layer above the insulating layer 221 and in the contact openings 222. Referring to FIGS. 7B and 8B, the method further includes patterning the electrically conducting layer 310 to form the contact fingers 32 and the connector 31. Patterning the electrically conducting layer 310 may include an etching process such as an anisotropic etching process using an etch mask 402 formed above electrically conducting layer 310, wherein the electrically conducting layers 310 is removed from those portions of the insulating layer 221 not covered by the etch mask 402. By suitably selecting the etch mask 402 the width of the contact fingers 32 and, therefore, the electrical resistance of the contact fingers 32 can be adjusted

Referring to the above, the electrically conducting layer 310 may be a doped polysilicon layer. According to one example, the doped polysilicon layer is deposited in a deposition process. According to another example, an intrinsic (not electrically conducting) polysilicon layer is deposited and the intrinsic polysilicon layer is doped using an implantation process to obtain the doped polysilicon layer. The doping process may take place before or after patterning the polysilicon layer. Referring to the above, different regions of the polysilicon layer may be doped differently in order to adjust electrical resistances of the gate fingers 32 that are formed based on the polysilicon layer.

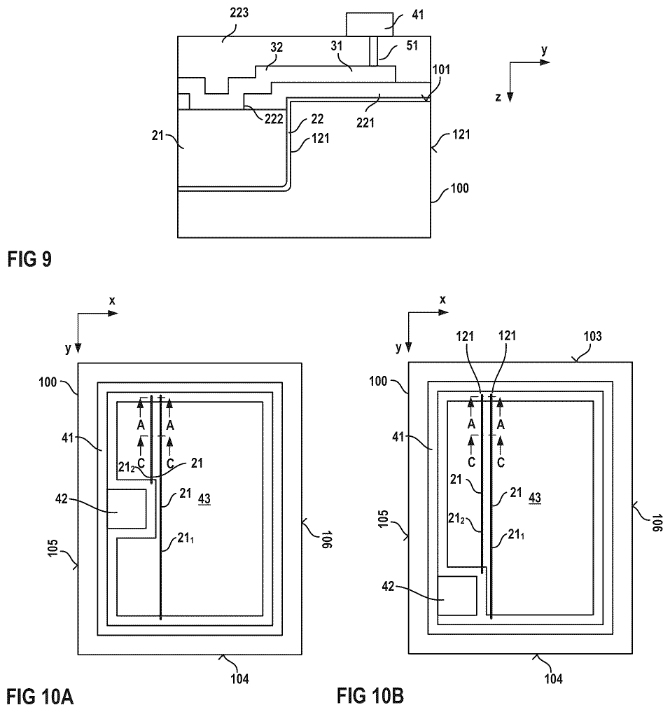

FIG. 9 illustrates a portion of a gate arrangement that is based on the gate arrangement explained herein before. This gate arrangement includes a further insulating layer 223 formed above the gate fingers 32 and connector 31, and a gate runner 41 arranged above the further insulating layer 223 and electrically connected the connector 31. The connector 31 may also be referred to as first gate runner and the gate runner 41 may also be referred to as second gate runner.

In the following, the insulating layer 221 is also referred to as first insulating layer, and the further insulating layer 223 is referred to as second insulating layer.

According to one example, the connector 31 is electrically connected to the gate runner 41 through an electrically conducting via 51 that extends through the second insulating layer 223.

The gate runner 41 includes an electrically conducting material such as, for example, aluminum (Al), copper (Cu), or an aluminum-copper alloy (AlCu). The electrically conducting via 51 includes tungsten (W), titanium (Ti), aluminum (Al), or copper (Cu), for example. The gate runner 41 may be formed by depositing an electrically conducting layer on top of the second insulating layer 223 and patterning the electrically conducting layer in an etching process to obtain the gate runner 41.

FIGS. 10A-10B schematically illustrate top views of transistor devices according to two different examples. Referring to FIGS. 10A-10B, each of the transistor devices includes a gate runner 41, a gate pad 42 connected to the gate runner 41, and a source electrode (source metallization) 43. The gate runner 41, in horizontal directions surrounds the source electrode 43. The gate pad 42 and the under source electrode 43 may include the same material as the gate runner 41 and may be formed by the same process as the gate runner 41. The gate pad 42 may adjoin the gate runner 41 (as illustrated). According to another example (not illustrated) the gate pad is spaced apart from the gate runner 41 and a resistor (gate resistor) is formed between the gate runner 41 and the gate pad 42.

The gate electrodes 21 are out of view in FIGS. 10A-10B. The position relative to the source electrode 43 and the gate runner 41 of two of the plurality of gate electrodes the transistor device may include is illustrated by bold lines in FIGS. 10A-10B. Each of these gate electrodes 21 is connected to the connector 31 through a respective contact finger 32 (which is also out of view in FIGS. 10A and 10B).

In the example illustrated in FIG. 10A, the gate pad 42 is arranged at a position that is essentially in the middle between two opposing sidewalls 103, 104 of the semiconductor body 100. In the example according to FIG. 10B, the gate pad 42 is arranged at a position that is close to a corner formed by two adjacent sidewalls 104, 105 of the semiconductor body 100. In each of these examples, the transistor device may include two types of gate electrodes 21, gate electrodes of a first type and gate electrodes of a second type. In FIGS. 10A and 10B, reference number 21₁ denotes a first type gate electrode and reference number 21₂ denotes a second type gate electrode. First type gate electrodes 21 have both the first longitudinal end 121 and the second longitudinal and 122 connected to the connector 31 (which is out of view in FIGS. 10A and 10B) and the gate runner 41. Second type gate electrodes only have one longitudinal end such as the first longitudinal end 121 connected to the connector 31 and the gate runner 41.

The gate pad 42 forms a gate node of the transistor device, and the source electrode 43 forms a source node of the transistor device. The source electrode 43 is spaced apart from each of the gate runner 41 and the gate pad 42. The connector 31, which is out of view in FIGS. 10A and 10B, is arranged below the gate runner 41. In the same way as the gate runner 41, the connector 31 forms a closed loop in a horizontal plane in which the connector 31 is arranged.

The semiconductor body 100 may include an inner region and an edge region. The inner region, which may also be referred to as active region, includes transistor cells and is essentially that region of the semiconductor body 100 arranged below the source electrode 43. The edge region is arranged between the inner region and the sidewalls 103-106 of the semiconductor body 100. According to one example, the connector 31, the gate runner 41 and the gate pad 42 are arranged above the edge region of the semiconductor body 100. According to one example, the gate fingers 32 are also arranged in the edge region of the semiconductor body 100.

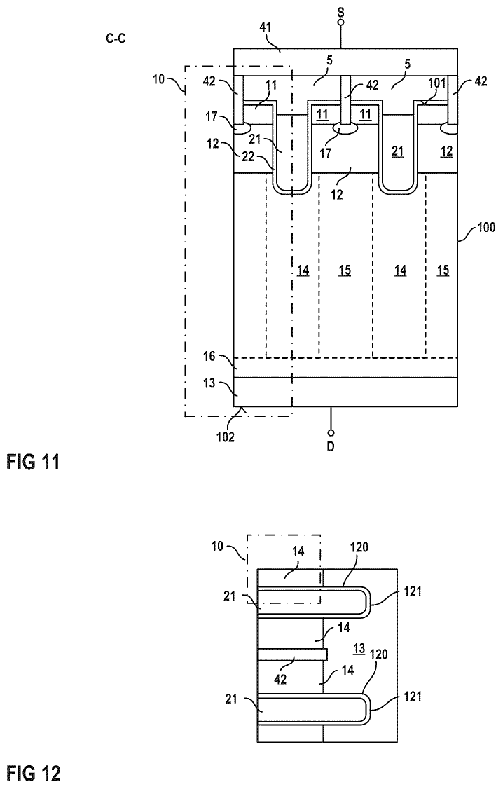

The inner region of the semiconductor body may include a plurality of transistor cells, wherein each of these transistor cells includes one of the gate electrodes 21 or a portion of one of the gate electrode 21. Transistor cells 10 according to one example are illustrated in FIG. 11. FIG. 11 illustrates a vertical cross-sectional view of the transistor device in a vertical section plane C-C illustrated in FIGS. 10A-10B.

Referring to FIG. 11, each transistor cell 10 includes a source region 11 of a first doping type, a body region 12 of a second doping type complementary to the first doping type, a drain region 13 of the first doping type, and a drift region 14 of the first doping type. The body region 12 adjoins the source region 12, so that a PN junction is formed between the source and body regions 11, 12. Furthermore, each of the source and body regions 11, 12 is connected to the source electrode 41. The source and body regions 11, 12 may be connected to the source electrode 41 through an electrically conducting via 42. According to one example, each of the source and body regions 11, 12 is ohmically connected to the electrically conducting via 42. For achieving an ohmic contact between the via 42 and the body region 12 a contact region 17 of the second doping type may be arranged between the body region 12 and the via 42, wherein the contact region 17 has a higher doping concentration than the body region 12.

Referring to FIG. 11, the source electrode 41 is formed on top of an insulating layer 5 that separates the source electrode 41 from the semiconductor body 100. The insulating layer 5 may include the first and second insulating layers 221, 223 explained herein before and/or other electrically insulating layers. The electrically conducting via 42 extends through the insulating layer 5 into the source and body regions 11, 12, for example.

Referring to FIG. 11, the drift region 14 adjoins the body region 12, so that a further PN junction is formed between the body region 12 and the drift region 14. The drift region 14 may adjoin the drain region 13. Optionally, a buffer region 16 of the first doping type is arranged between the drift region 14 and the drain regions 13. The buffer region 16 may have a doping concentration that is lower than a doping concentration of the drain region 13 and higher than a doping concentration of the drift region 14.

In the example illustrated in FIG. 11, the transistor device is a vertical transistor device. In this example, the drain region 13 is spaced apart from the body region 12 in the vertical direction z of the semiconductor body 100.

As can be seen from FIG. 11, the same gate electrode may form gate electrodes 21 of two neighboring transistor cells 10, and body regions of two (other) neighboring transistor cells may be formed by one contiguous doped semiconductor region. The transistor cells may have one common drift region 11, one common drain region 13 and, optionally, one common buffer region 16.

According to one example, the transistor device is a superjunction transistor device. In this example, each transistor cell further includes a compensation region 15 of the second doping type adjacent to the drift region 14 and connected to the source electrode 41. In the example illustrated in FIG. 11, the compensation regions 15 adjoin the body regions 12, so that the compensation regions 15 are connected to the source electrode 41 via the body regions 12, the contact regions 17, and the electrically conducting vias 42.

The transistor device can be operated in a conventional way by applying a drive voltage between the gate pad 42 (not illustrated in FIG. 11) and the source electrode 43. The transistor device is in the on-state (conducting state) when the drive voltage is such that conducting channels are generated in the body regions 12 along the gate dielectrics 22 between the source regions 11 and the drift regions 14. The transistor device is in the off-state (blocking state) when the electrically conducting channels are interrupted. The transistor device can be implemented as an N-type transistor device or as a P-type transistor device. An N-type transistor device, for example, is in the on-state, when the drive voltage is higher than a predefined positive threshold voltage and in the off-state, when the drive voltage is below the threshold voltage.

In an N-type transistor device, the doped regions of the first doping type are N-type regions and the doped regions of the second doping type are P-type regions. In a P-type transistor device, the doped regions of the first doping type are P-type regions and the doped regions of the second doping type are N-type regions.

In an N-type transistor device, doping concentrations of the active device regions are selected from the following ranges, for example
Source region 11: 5E19 cm⁻³-5E20 cm⁻³
Body region 12: 3E19 cm⁻³-3E20 cm⁻³
Drain region 13: 5E18 cm⁻³-5E20 cm⁻³
Drift region 14: 7E15 cm⁻³-7E16 cm⁻³
Compensation region 15: 7E15 cm⁻³-7E16 cm⁻³
Buffer region 16: 5E15 cm⁻³-5E16 cm⁻³
Body contact region 17: 1E20 cm⁻³-1E21 cm⁻³

Referring to FIG. 11, each of the source and body regions 11, 12 adjoins a respective gate dielectric 22. In longitudinal directions of the gate trenches, the source regions 14 may terminate before longitudinal ends of the gate trenches. This is illustrated in FIG. 12 which shows a horizontal cross-sectional view of one portion of the gate arrangement in a region close to the first longitudinal ends 121 in a section plane cutting through the source regions 14. As can be seen from FIG. 12, the source regions 14 do not extend to the longitudinal ends 121 of the gate trenches 120, wherein the body regions 12 surround the longitudinal ends 121 of the gate trenches 120.

In the gate arrangement explained herein before in which the insulating layer 221 is produced independent of the gate dielectrics 22 the thickness of the insulating layer 221 can be adjusted independent of the thickness of the gate dielectric 22. This makes it possible to implement the gate dielectric 22 as thin as desired to achieve desired electrical characteristics of the transistor cells 10 and to implement the insulating layer 221 as thick as required to ensure sufficient electrical insulation between the gate fingers 32 and the (first) connector 31 on one side and regions of the semiconductor body 100 that have the same electrical potential as the source electrode 43 on the other side. In particular along the first surface 101, in corners between the first surface 101 and sidewalls of the gate trenches 120, particularly high electric fields may occur that are absorbed by the insulating layer 221.

Furthermore, the electrical resistance between the gate electrodes 21 and the connector 31 can be easily adjusted suitably adjusting the size of the contact openings 222.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method, comprising:
forming a plurality of gate electrodes such that each gate electrode is arranged in a respective gate trench extending from a first surface of a semiconductor body into the semiconductor body and is dielectrically insulated from the semiconductor body by a respective gate dielectric;
forming an insulating layer above the first surface of the semiconductor body and the gate electrodes;
forming at least one contact opening in the insulating layer above each gate electrode;
forming a plurality of contact fingers, wherein each contact finger is connected to a respective gate electrode in a respective contact opening; and
forming a connector connecting the contact fingers with each other.

2. The method of claim 1, wherein the contact fingers and the connector are formed by a same process.

3. The method of claim 2, wherein forming the contact fingers and the connector comprises:
forming an electrically conducting layer above the first insulating layer; and
patterning the electrically conducting layer.

4. The method of claim 1, wherein the gate trenches are parallel to each other.

5. The method of claim 1, further comprising:
forming the gate dielectrics and the gate electrodes.

6. The method of claim 5, wherein forming the gate dielectrics comprises a thermal oxidation process in which a gate dielectric layer is formed along sidewalls and bottoms of the gate trenches and on the first surface of the semiconductor body.

7. The method of claim 6, further comprising:
before forming the insulating layer, removing the gate dielectric layer at least from portions of the first surface.

8. The method of claim 6, wherein the gate dielectric layer remains on the first surface, so that the first insulating layer is formed above the gate dielectric layer.

9. The method of claim 1, wherein the insulating layer is a first insulating layer, the method further comprising:
forming a second insulating layer above the contact fingers, the connector, and the first insulating layer; and
forming a gate runner connected to the connector above the second insulating layer.

10. The method of claim 1, wherein the insulating layer is thicker than the gate dielectrics.

11. A transistor device comprising a gate arrangement, wherein the gate arrangement comprises:
a plurality of gate electrodes, wherein each gate electrode is arranged in a respective gate trench extending from a first surface of a semiconductor body into the semiconductor body and is dielectrically insulated from the semiconductor body by a respective gate dielectric;
an insulating layer above the first surface of the semiconductor body and the gate electrodes;
at least one contact opening in the insulating layer above each gate electrode;
a plurality of contact fingers, wherein each contact finger is connected to a respective gate electrode in a respective contact opening; and
a connector connecting the contact fingers with each other.

12. The transistor device of claim 11, wherein the insulating layer is a first insulating layer, and wherein the gate arrangement further comprises:
a second insulating layer formed above the contact fingers, the connector, and the first insulating layer; and
a gate runner formed above the second insulating layer and electrically connected to the connector.

13. The transistor device of claim 12, further comprising:
a plurality of transistor cells each comprising a source region and at least a portion of a respective one of the gate electrodes; and
a source electrode connected to the source region of each of the transistor cells,
wherein the gate runner, in a horizontal plane, surrounds the source electrode.

14. The transistor device of claim 12, further comprising:
a gate pad connected to the gate runner.
